(19) United States
(12) Patent Application Publication
(10) Pub. No.: US 2008/0219462 A1
(43) Pub. Date: Sep. 11, 2008

(54) Device and method for shaping a digital audio signal

(76) Inventor: Dieter Burmester, Berlin (DE)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/074,759

(22) Filed: Mar. 6, 2008

Related U.S. Application Data
(60) Provisional application No. 60/893,637, filed on Mar. 8, 2007.

(30) Foreign Application Priority Data
Mar. 8, 2007 (DE) 10 2007 011 436.4

(51) Int. Cl. H03G 3/00

(52) U.S. Cl. 381/61

(57) ABSTRACT

A device (100) for shaping a digital audio signal is provided. The device comprises an input (110) for a digital audio input signal, an output (120) for a shaped digital audio output signal, and at least one of the following means: a means (m1) for inserting an echo into the digital audio input signal; a means (m2) for inserting a channel crosstalk into the digital audio input signal; a means (m3) for inserting a distortion into the digital audio input signal; a low-pass filter (m4) for filtering the digital audio input signal; a dynamic range compressor (m5) for carrying out a dynamic range compression on the digital audio input signal.

The present invention relates to a device and a method for shaping a digital audio signal. In accordance with a further aspect, the present invention also relates to the use of the device and to a digital sound carrier on which is stored an audio signal shaped according to the invention.

The compact disc (CD) was developed at the end of the 1970s and was presented to the public for the first time in 1981. In the meantime, the CD has developed into the standard for the digital storage of audio signals and to date has achieved sales of more than 100 million. Owing to the digital storage of the audio data, the signal read from a CD is not subject to any electronic or mechanical distortion such as occurs for instance during the analog scanning of a phonograph record. Contrary to the objectively physical advantages of sound storage on CD, however, many listeners perceive the sound of a record to be “more lively” and “warmer”. This may be due to nostalgic aspects, on the one hand, since a listener's sound conception is shaped by his/her listening habits. On the other hand, however, psychoacoustic effects can also result in record sound being preferred.

With regard to the abovementioned disadvantages of the prior art, the present invention proposes a method in accordance with claim 1 and a device in accordance with claim 13. Further aspects, advantages and details of the present invention are evident from the subclaims, the description and the accompanying drawings.

A first exemplary embodiment of the present invention provides a method for shaping a digital audio signal. The method comprises the steps of: providing a digital audio input signal; performing at least one of the following steps for shaping a digital audio output signal: inserting an echo into the digital audio input signal; inserting a channel crosstalk into the digital audio input signal; inserting a distortion into the digital audio input signal; filtering the digital audio input signal by means of a low-pass filter; carrying out a dynamic range compression on the digital audio input signal; and also the step of providing the shaped digital audio output signal. In particular, in this case the signal obtained in one of the substeps can be used as audio input signal for the next substep. It is furthermore possible to perform all of the above steps, in particular also in the order specified.

By means of the method in accordance with the exemplary embodiment described above, the digital audio input signal can be shaped in such a way that the digital output signal corresponds or is at least similar to the sound impression of a record. From a technical standpoint, although this is tantamount to impairing the signal properties of the digital input signal, the actual listening impression can be improved for the nostalgic or psychoacoustic reasons mentioned in the introduction.

A further exemplary embodiment of the present invention provides a device for shaping a digital audio signal. In this case, the device comprises an input for a digital audio input signal, an output for a shaped digital audio output signal, at least one of the following means: a means for inserting an echo into the digital audio input signal; a means for inserting a channel crosstalk into the digital audio input signal; a means for inserting a distortion into the digital audio input signal; a low-pass filter for filtering the digital audio input signal; a dynamic range compressor for carrying out a dynamic range compression on the digital audio input signal. One or more of said means is or are typically realized by a digital signal processor (DSP).

The device in accordance with the above exemplary embodiment is suitable for shaping a digital audio signal provided at the input in such a way that the digital output signal corresponds or is at least similar to the sound impression of a record. From a technical standpoint, although this is tantamount to impairing the signal properties of the digital input signal, the actual listening impression can be improved for the nostalgic or psychoacoustic reasons mentioned in the introduction.

In accordance with one development of the above exemplary embodiment, the device furthermore comprises at least one of the following controllers: a controller for setting a temporal delay of the echo; a controller for setting the crosstalk attenuation of the channel crosstalk; a controller for setting a distortion curve; a controller for setting a slope gradient and/or a cut-off frequency of the low-pass filter; a controller for setting a characteristic curve of the dynamic range compressor.

This enables a listener to adapt the sound impression to his/her personal preferences.

Exemplary embodiments of the present invention will now be explained with reference to the accompanying drawings, in which:

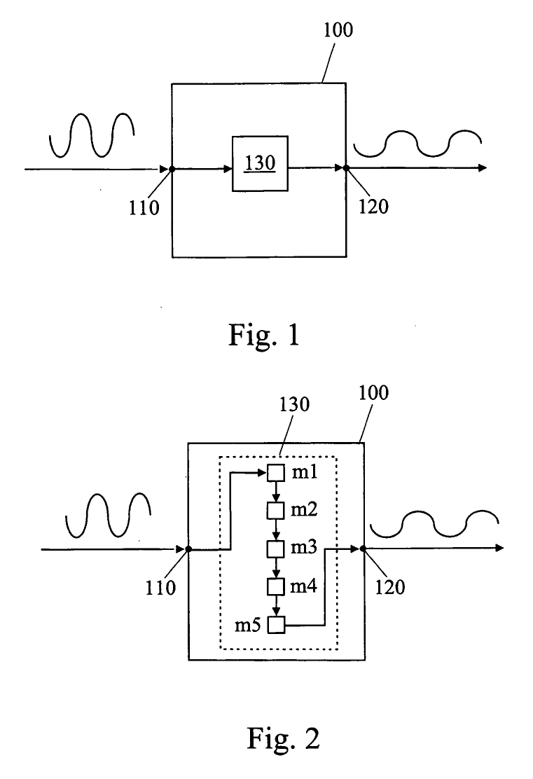

FIG. 1 shows a device in accordance with a first exemplary embodiment of the present invention.

FIG. 2 shows a device in accordance with a further exemplary embodiment of the present invention.

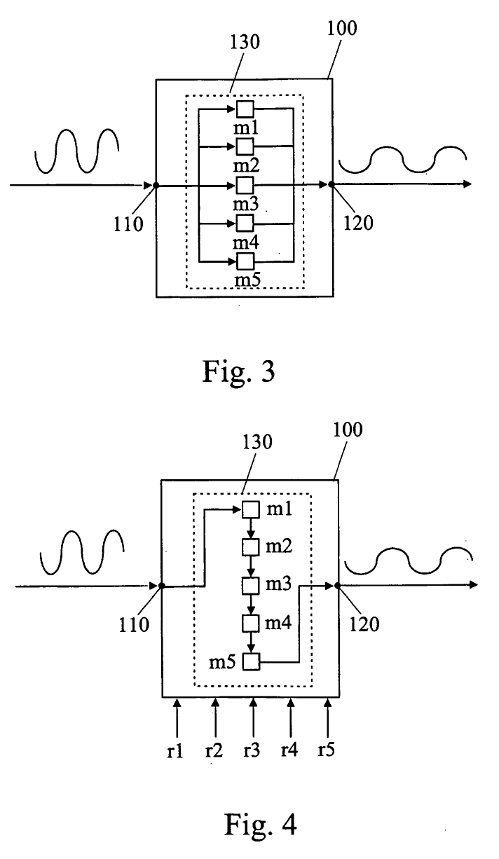

FIG. 3 shows a device in accordance with yet another exemplary embodiment of the present invention.

FIG. 4 shows a device in accordance with another exemplary embodiment of the present invention.

FIG. 1 shows a device 100 in accordance with a first exemplary embodiment of the present invention. The device 100 is set up for shaping a digital audio signal. In this case, the device 100 has an input 110 for a digital audio input signal, and an output 120 for a shaped digital audio output signal. Furthermore, the device comprises a digital signal processor (DSP) 130. A digital audio input signal fed into the input 120 is transferred to the DSP, which shapes the signal to form a desired digital output signal. The audio input signal present at the input 120 is for example an audio signal read from a CD. The digital audio input signal therefore has the typical sound impression of a CD with low total harmonic distortion, very good dynamic range, very good channel separation and a linear frequency response. The device 100 and in particular DSP 130 are set up, then, in such a way that they convert this CD sound impression in order to generate an audio output signal which corresponds or is at least similar to the sound impression of a record. For this purpose, the device 100 or the DSP 130 comprises a means m1 for inserting an echo into the digital audio input signal and/or a means m2 for inserting a channel crosstalk into the digital audio input signal and/or a means m3 for inserting a distortion into the digital audio input signal and/or a low-pass filter m4 for filtering the digital audio input signal and/or a dynamic range compressor m5 for carrying out a dynamic range compression on the digital audio input signal. With the aid of said means, the digital audio input signal can be shaped such that the digital output signal provided at the output 120 has a record-like sound impression.

FIG. 2 shows a device 100 in accordance with a further exemplary embodiment of the present invention, in which all of the means m1 to m5 described above are provided in the device. The means are connected to one another in such a way that the means m1 for inserting an echo receives the digital audio input signal as input. The means m1 then adds an echo to the signal. In this case, a postecho or a pre-echo or else both a postecho and a pre-echo can be added to the audio input signal. If pre- and postecho are added, then the temporal shift of pre- and postecho is typically identical. If required, however, the temporal shift can also be chosen differently for pre- and postecho. In this case, typical temporal shifts are within the range of 1 second to 5 seconds. In order to ensure the audio data storage required for generating the echo, the means m1 for inserting an echo into the digital audio input signal can comprise a ping-pong buffer or a ring memory. The output signal of the means m1, provided with an echo, is then fed into the means m2 for inserting a channel crosstalk. The audio signal is typically a stereo signal without channel crosstalk. However, the means m2 can insert a channel crosstalk with a crosstalk attenuation within the range of 15 dB to 75 dB. The audio signal modified in this way is subsequently fed into a means m3 for inserting a distortion. In this case, a quadratic or cubic function is typically used as distortion characteristic curve in order to achieve a distortion similar to the sound impression of a record. The audio signal modified in this way is subsequently fed into a low-pass filter m4. The low-pass filter typically cuts off within the range of 15 kHz to 20 kHz. Moreover, the low-pass filter typically has a slope gradient within the range of 15 dB/dec to 40 dB/dec. The frequency response of a record can be simulated in this way. The audio signal thus obtained is subsequently fed into a dynamic range compressor m5. The latter reduces the CD's very good dynamic range, that is to say the loudness separation between the loudest and quietest passages, to a range such as can typically be expected in the sound impression of records. The dynamic compressor typically has a piecewise linear characteristic curve. Even though all of the means m1 to m5 are illustrated in FIG. 2, it is nevertheless pointed out that individual means from among said means can be omitted or turned off as required. It is furthermore pointed out that the echo and/or the channel crosstalk and/or the distortion and/or the dynamic range compression can be carried out both in a frequency-dependent manner and in a frequency-independent manner. Thus, a frequency-independent variation may possibly be easier to realize, but a frequency-dependent variation will typically achieve a “more realistic” listening result.

The device in accordance with the above exemplary embodiment is suitable for shaping a digital audio signal provided at the input in such a way that the digital output signal corresponds or is at least similar to the sound impression of a record. From a technical standpoint, although this is tantamount to impairing the signal properties of the digital input signal, the actual listening impression can be improved for the nostalgic or psychoacoustic reasons mentioned in the introduction.

FIG. 3 shows a device 100 in accordance with yet another exemplary embodiment of the present invention. The device 100 in accordance with FIG. 3 differs from the exemplary embodiment in accordance with FIG. 2 in that the audio input signal is processed in parallel instead of sequentially. By way of example, such a solution can be realized by means of the implementation of a multiplex method. However, the device in accordance with the exemplary embodiment shown in FIG. 3 also converts the digital audio input signal into a digital audio output signal having a record-like sound impression.

FIG. 4 shows a device in accordance with another exemplary embodiment of the present invention, in which the device 100 furthermore comprises a controller r1 for setting a temporal delay of the echo, a controller r2 for setting the crosstalk attenuation of the channel crosstalk, a controller r3 for setting a distortion curve, a controller r4 for setting a slope gradient and/or a cut-off frequency of the low-pass filter, and a controller r5 for setting a characteristic curve of the dynamic range compressor. Even though a respective dedicated controller r1 to r5 is illustrated for each of the means m1 to m5, some of the controllers can also be omitted or combined. Furthermore, the controllers can also serve for selectively turning off individual means. The provision of the controllers r1 to r5 enables a listener to adapt the sound impression generated by the device 100 to his/her personal preferences.

Furthermore, the device can comprise a digital-to-analog converter (not shown), which converts the digital audio signal provided at the output 120 into an analog signal. The D/A converter can also be integrated into the DSP 130.

The device in accordance with the exemplary embodiments described above is suitable for carrying out a method for shaping a digital audio signal. In such a method, the “hard” and “cold” CD sound is approximated to the “warm” and “lively” sound impression of a record by means of the described steps of inserting an echo and/or inserting a channel crosstalk and/or inserting a distortion and/or filtering the digital signal by means of a low-pass filter and/or carrying out a dynamic range compression. From a technical standpoint, although this is tantamount to impairing the signal properties of the digital input signal, the actual listening impression can be improved for the nostalgic or psychoacoustic reasons mentioned in the introduction.

The devices in accordance with the embodiments of the present invention can be formed for example as separate components for hi-fi systems. Devices in accordance with the embodiments of the present invention can likewise be integrated into CD players or DVD players. Furthermore, it is also conceivable to integrate such devices into computers, digital televisions, MP3 players or similar devices that operate with digital audio information, in order to provide a record-like sound impression.

Furthermore, it is possible, of course, for a digital audio signal shaped by means of a method according to an exemplary embodiment of the present invention to be stored again on a digital sound carrier, for example a CD. In this way, the sound carrier prerecorded in this way can be played back on a conventional CD player and nevertheless has the sound impression of a record.

The embodiments described above use a digital signal processor for realizing the different means m1 to m5. It is expressly pointed out, however, that such means can also be realized by individual hardware components. In particular, digital electronic components, e.g. integrated circuits, can be used in this case. However, it is also possible to realize some components, such as, for example, the means m3 for inserting the distortion, using analog components, such as a tube for instance. In this case, the digital signal is converted into an analog signal by means of a D/A converter upstream of the analog component and, after modulation by the analog component, is converted back into a digital signal by means of an A/D converter.

The present invention has been explained on the basis of exemplary embodiments. These exemplary embodiments should in no way be understood as being restrictive for the present invention.

1. A method for shaping a digital audio signal, comprising the steps of:
(a) providing a digital audio input signal
(b) performing at least one of the following steps for shaping a digital audio output signal:
(b1) inserting an echo into the digital audio input signal;
(b2) inserting a channel crosstalk into the digital audio input signal;
(b3) inserting a distortion into the digital audio input signal;
(b4) filtering the digital audio input signal by means of a low-pass filter;
(b5) carrying out a dynamic range compression on the digital audio input signal;
(c) providing the shaped digital audio output signal.

2. The method as claimed in claim 1, wherein in step (b1) the echo is a postecho.

3. The method as claimed in claim 1 or 2, wherein in step (b1) the echo is a pre-echo.

4. The method as claimed in any of the preceding claims, wherein in step (b1) the echo is a pre-echo and a postecho, wherein the pre-echo and the postecho have the same temporal shift.

5. The method as claimed in any of the preceding claims, wherein the postecho and/or the pre-echo have/has a temporal shift within the range of 1 s to 5 s.

6. The method as claimed in any of the preceding claims, wherein the audio signal is a stereo signal and step (b2) involves inserting a channel crosstalk with a crosstalk attenuation within the range of 15 dB to 75 dB.

7. The method as claimed in any of the preceding claims, wherein a quadratic or cubic function or an even higher-order function is used as distortion characteristic curve in step (b3).

8. The method as claimed in any of the preceding claims, wherein in step (b4) the low-pass filter has a slope gradient within the range of 15 dB/dec to 40 dB/dec.

9. The method as claimed in any of the preceding claims, wherein in step (b4) the low-pass filter cuts off within the range of 10 kHz to 20 kHz.

10. The method as claimed in any of the preceding claims, wherein in step (b) the signal obtained from one of substeps (b1) to (b5) is respectively used as input signal for the next substep.

11. The method as claimed in any of the preceding claims, wherein all of steps (b1) to (b5) are performed.

12. The method as claimed in claim 10, wherein steps (b1) to (b5) are performed in this order.

13. A device (100) for shaping a digital audio signal, comprising
an input (110) for a digital audio input signal,
an output (120) for a shaped digital audio output signal,
at least one of the following means:
(m1) a means for inserting an echo into the digital audio input signal;
(m2) a means for inserting a channel crosstalk into the digital audio input signal;
(m3) a means for inserting a distortion into the digital audio input signal;
(m4) a low-pass filter for filtering the digital audio input signal;
(m5) a dynamic range compressor for carrying out a dynamic range compression on the digital audio input signal.

14. The device (100) as claimed in claim 13, wherein the means (m1) for inserting an echo into the digital audio input signal and/or the means (m2) for inserting a channel crosstalk into the digital audio input signal and/or the means (m3) for inserting a distortion into the digital audio input signal and/or the low-pass filter (m4) for filtering the digital audio input signal and/or the dynamic range compressor (m5) for carrying out a dynamic range compression on the digital audio input signal comprise a digital signal processor (130).

15. The device as claimed in claim 13 or 14, wherein the means (1) for inserting an echo into the digital audio input signal comprises a ping-pong buffer or a ring memory.

16. The device as claimed in any of claims 13 to 15, wherein the device comprises all of the means (m1) to (m5).

17. The device as claimed in any of claims 13 to 16, furthermore comprising at least one of the following controllers:
(r1) a controller for setting a temporal delay of the echo;
(r2) a controller for setting the crosstalk attenuation of the channel crosstalk;
(r3) a controller for setting a distortion curve;
(r4) a controller for setting a slope gradient and/or a cut-off frequency of the low-pass filter;
(r5) a controller for setting a characteristic curve of the dynamic range compressor.

18. The device as claimed in any of claims 13 to 17, wherein the device is set up for performing a method as claimed in any of claims 1 to 12.

19. The use of a device as claimed in any of claims 13 to 18 for performing a method as claimed in any of claims 1 to 12.

20. A digital sound carrier on which is stored a digital audio signal obtained according to a method as claimed in any of claims 1 to 12.
